(19) United States
(12) Patent Application Publication
(10) Pub. No.: US 2015/0101851 A1
(43) Pub. Date: Apr. 16, 2015

(54) PRINTED CIRCUIT BOARD AND METHOD OF MANUFACTURING THE SAME

(71) Applicant: SAMSUNG ELECTRO-MECHANICS CO., LTD., Suwon-Si (KR)

(72) Inventors: Young Gwan Ko, Suwon-Si (KR); Tae Hong Min, Suwon-Si (KR); Sang Hoon Kim, Suwon-Si (KR); Suk Hyeon Cho, Suwon-Si (KR)

(73) Assignee: SAMSUNG ELECTRO-MECHANICS CO., LTD., Suwon-Si (KR)

(21) Appl. No.: 14/459,320

(22) Filed: Aug. 14, 2014

(30) Foreign Application Priority Data
Oct. 10, 2013 (KR) 10-2013-0120769

(51) Int. Cl. H05K 1/03; C03B 27/04; H05K 3/44; H05K 1/02; H05K 3/10; H05K 3/00

(52) U.S. Cl. CPC H05K 1/0306; H05K 3/10; H05K 3/0073; H05K 3/44; H05K 1/0271; H05K 1/0298; C03B 27/04
USPC 174/258; 427/96.1; 427/554

(57) ABSTRACT

There are provided a printed circuit board and a method of manufacturing the same. The printed circuit board according to an exemplary embodiment of the present disclosure includes an insulating layer including a glass core and a tempering treatment layer formed on one surface of the glass core, such that a problem about warpage may be minimized and an effect capable of thinning the printed circuit board may be achieved.

### CROSS-REFERENCE TO RELATED APPLICATION

This application claims the benefit of Korean Patent Application No. 10-2013-0120769, filed on Oct. 10, 2013, entitled “Printed Circuit Board and Method of Manufacturing the Same” which is hereby incorporated by reference in its entirety into this application.

### BACKGROUND

The present disclosure relates to a printed circuit board and a method of manufacturing the same.

In accordance with the recent development of electronic industries, a demand for multi-functional and light and small electronic components has been rapidly increased. Therefore, there is a need to increase a wiring density of a printed circuit board on which the electronic components are mounted and reduce a thickness thereof.

Particularly, since a typical build-up wiring board is used as a product in a state in which a build-up layer is formed on a core substrate and the core substrate is formed, the entire thickness of the wiring board has been increased. As the core substrate, a typical insulating film, a prepreg manufactured by impregnating glass cloth in a resin composition varnish, or a copper clad laminate (CCL) may be used. In the case in which the thickness of the wiring board is large, a length of the wiring becomes long and a lot of time is spent to process a signal, thereby causing a problem countering with a requirement of the increase in the wiring density.

In addition, since thinness is progressed according to a trend toward fineness of an interval between pads connecting a line, a space, and a chip to one another, and mobilization and high multi-layer according to high integration is required, manufacturing costs have been sharply increased. While a printed circuit board becomes thin, warpage is relatively likely to occur and it is difficult to adjust an occurrence amount of warpage. This may cause defect during a process of a chip assembly and affect reliability.

Meanwhile, although Patent Document 1 discloses features in which a glass board manufactured by a chemical tempering process implements high thermal conductivity in a glass board for information recoding medium, there is a limit related to decreasing the warpage and thinning the board.
Patent Document 1: Japanese Patent Laid-Open Publication No. 2008-130179

### SUMMARY

An aspect of the present disclosure may provide a printed circuit board in which an insulating layer including a glass core and a tempering treatment layer formed on one surface of the glass core is embedded.

An aspect of the present disclosure may also provide a method of manufacturing a printed circuit board capable of solving a problem about warpage of the board and minimizing a thickness of the board by using the insulating layer.

According to an aspect of the present disclosure, a printed circuit board may include: an insulating layer including a glass core and a tempering treatment layer formed on one surface of the glass core; and a circuit layer formed on the insulating layer.

The tempering treatment layer may be formed by treating one surface of the glass core by an air cooled tempering process.

The tempering treatment layer may be formed by treating one surface of the glass core by a chemical tempering process.

The printed circuit board may further include a build-up layer including a build-up insulating layer and a build-up circuit layer on one surface or the other surface of the circuit layer.

The printed circuit board may further include a solder resist layer formed on the outermost layer of the build-up layer.

According to another aspect of the present disclosure, a method of manufacturing a printed circuit board may include: preparing a glass core; providing an insulating layer by forming a tempering treatment layer on one surface of the glass core; and forming a circuit layer on the insulating layer.

In the forming of the tempering treatment layer, the tempering treatment layer may be formed by treating one surface of the glass core by an air cooled tempering process.

In the forming of the tempering treatment layer, the tempering treatment layer may be formed by treating one surface of the glass core by a chemical tempering process.

The forming of the circuit layer on the insulating layer may include: forming a via hole in the insulating layer by a laser machining; and forming the circuit layer including a via by depositing a metal layer on the via hole and both surfaces of the insulating layer.

The method may further include, after the forming of the circuit layer, forming a build-up layer including a build-up insulating layer and a build-up circuit layer on one surface or the other surface of the circuit layer.

The method may further include, after the forming of the build-up layer, forming a solder resist layer on the outermost layer of the build-up layer.

The providing of the insulating layer may include: forming the tempering treatment layer on one surface of the glass core; and polishing and removing a portion of the tempering treatment layer in a thickness direction.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a cross-sectional view of a multi-layer printed circuit board according to an exemplary embodiment of the present disclosure;

FIG. 2 is a cross-sectional view of a multi-layer printed circuit board according to another exemplary embodiment of the present disclosure;

FIGS. 3 through 6 are cross-sectional views showing a manufacturing process flow in order to describe a method of manufacturing a printed circuit board according to an exemplary embodiment of the present disclosure; and

FIGS. 7 through 10 are cross-sectional views showing a manufacturing process flow in order to describe a method of manufacturing a printed circuit board according to another exemplary embodiment of the present disclosure.

### DETAILED DESCRIPTION

The objects, features and advantages of the present disclosure will be more clearly understood from the following detailed description of the exemplary embodiments taken in conjunction with the accompanying drawings. Throughout the accompanying drawings, the same reference numerals are used to designate the same or similar components, and redundant descriptions thereof are omitted. Further, in the following description, the terms “first,” “second,” “one side,” “the other side” and the like are used to differentiate a certain component from other components, but the configuration of such components should not be construed to be limited by the terms. Further, in the description of the present disclosure, when it is determined that the detailed description of the related art would obscure the gist of the present disclosure, the description thereof will be omitted.

Hereinafter, exemplary embodiments of the present disclosure will be described in detail with reference to the accompanying drawings.

Printed Circuit Board

### First Exemplary Embodiment

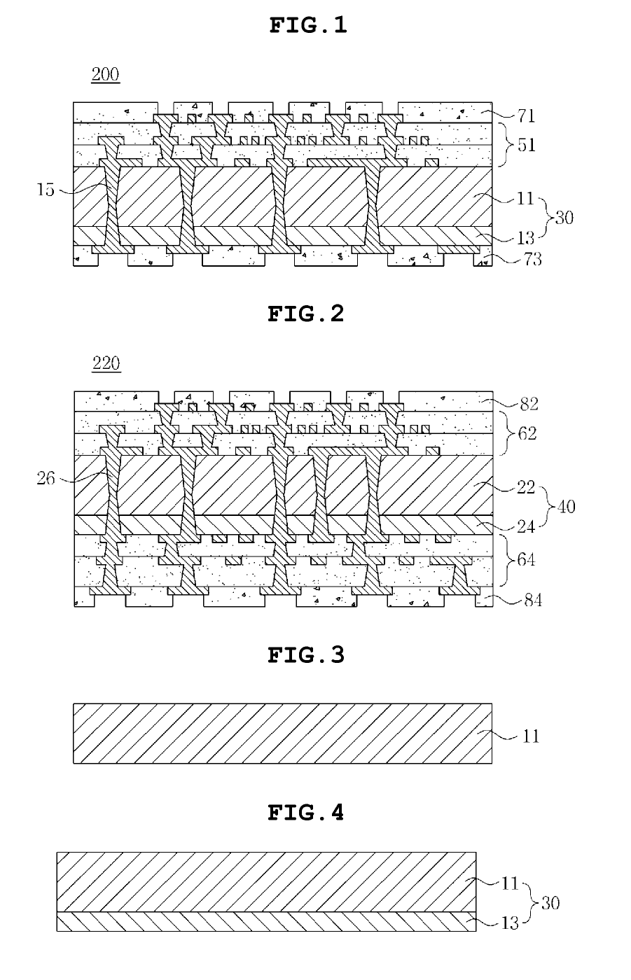

FIG. 1 is a cross-sectional view of a multi-layer printed circuit board according to an exemplary embodiment of the present disclosure.

Referring to FIG. 1, a multi-layer printed circuit board 200 according to an exemplary embodiment of the present disclosure may include an insulating layer 30 including a glass core 11 and a tempering treatment layer 13 formed on one surface of the glass core 11, and a circuit layer 15 formed on the insulating layer 30.

A material which may be used as the glass core 11 may be, for example, pure silica, soda lime glass, borosilicate glass, or alumo-silicate glass, but is not particularly limited thereto.

The tempering treatment layer 13 may be formed by treating one surface of the glass core 11 by an air cooled tempering process or a chemical tempering process.

The tempering treatment layer 13 may be formed by, for example, the air cooled tempering process in which one surface of the glass core 11 is first heated under a temperature condition 500 to 600° C. and is rapidly cooled under a wind pressure condition of 15 to 30 kPa, but is not particularly limited thereto.

In addition, the tempering treatment layer 13 may be formed by the chemical tempering process in which one surface of the glass core 11 is immersed in molten salt to perform an ion-exchange reaction. The molten salt may be defined as follows. For example, if potassium nitrate (KNO₃) is put into a bath and a temperature is heated to about 380° C., potassium nitrate (KNO₃) is changed to a liquid state. This potassium nitrate in the liquid state may be referred to as the molten salt. Next, if the bath has a temperature condition of 450 to 500° C. and one surface of the glass core 11 is immersed in the bath into which the molten salt is put for several hours, the ion-exchange reaction is performed in which sodium (Na⁺) ions are moved from a surface of the immersed glass core 11 and potassium (K⁺) ions are substituted into the positions from which sodium ions are moved, thereby making it possible to form the tempering treatment layer 13 having compression stress on the surface of the glass core 11, but the present disclosure is not particularly limited thereto.

According to an exemplary embodiment of the present disclosure, the insulating layer 30 including the tempering treatment layer 13 formed on one surface of the glass core 11 may have an effect improving bending strength only with thin thickness, thereby preventing a warpage phenomenon.

The insulating layer 30 according to an exemplary embodiment of the present disclosure may have a via hole, and may form the circuit layer including a circuit pattern on one surface or the other surface thereof. In addition, the printed circuit board 200 may further include a build-up layer 51 including a build-up insulating layer and a build-up circuit layer on one surface of the circuit layer 15. By the configuration as described above, the printed circuit board according to an exemplary embodiment of the present disclosure may be formed in an asymmetrical shape.

In addition, the printed circuit board may further include a solder resist layer 71 formed on the outermost layer of the build-up layer 51. The solder resist layer 71 may be formed on the outermost layer of the build-up layer 51 to protect and electrical insulate the circuit pattern. The solder resist layer 71 may be provided with an open part to expose a connection terminal formed on the outermost layer of the build-up layer 51 connected to other electronic products. In addition, the solder resist layer 73 may also be formed on a surface of the insulating layer 30 on which the build-up layer 51 is not formed.

### Second Exemplary Embodiment

FIG. 2 is a cross-sectional view of a multi-layer printed circuit board according to another exemplary embodiment of the present disclosure.

Referring to FIG. 2, a multi-layer printed circuit board 220 according to another exemplary embodiment of the present disclosure may include an insulating layer 40 including a glass core 22 and a tempering treatment layer 24 formed on one surface of the glass core 22, and a circuit layer 26 formed on the insulating layer 40.

In addition, the printed circuit board 220 may further include build-up layers 62 and 64 including a build-up insulating layer and a build-up circuit layer on one surface and the other surface of the circuit layer 26. In this case, the multi-layer printed circuit board 220 may be formed in a symmetrical or asymmetrical shape by stacking thicknesses of the build-up layer 62 stacked on one surface and the build-up layer 64 stacked on the other surface of the circuit layer 26 to be equal to each other or be different from each other. By the configuration as described above, when designing additional stacking processes on an upper and lower portions of the multi-layer printed circuit board 220, the build-up layers 62 and 64 are formed in the symmetrical shape or the asymmetrical shape, thereby making it possible to appropriately adjust the warpage.

In addition, the printed circuit board may further include solder resist layers 82 and 84 formed on the outermost layers of the build-up layers 62 and 64. The solder resist layers 82 and 84 may be formed on the outermost layers of the build-up layers 62 and 64 to protect and electrical insulate the circuit pattern. The solder resist layers 82 and 84 may be provided with open parts to expose connection terminals formed on the outermost layers of the build-up layers 62 and 64 connected to other electronic products.

Method of Manufacturing Printed Circuit Board

### First Exemplary Embodiment

FIGS. 3 through 6 are cross-sectional views showing a manufacturing process flow in order to describe a method of manufacturing a printed circuit board according to an exemplary embodiment of the present disclosure.

Referring to FIG. 3, a method of manufacturing a printed circuit board 100 according to an exemplary embodiment of the present disclosure may include preparing a glass core 11. A material which may be used as the glass core 11 may be, for example, pure silica, soda lime glass, borosilicate glass, or alumo-silicate glass, but is not particularly limited thereto.

Referring to FIG. 4, a method of manufacturing a printed circuit board 100 according to an exemplary embodiment of the present disclosure may include providing an insulating layer 30 by forming a tempering treatment layer 13 on one surface of the glass core 11.

The tempering treatment layer 13 may be formed by, for example, the air cooled tempering process in which one surface of the glass core 11 is first heated under a temperature condition 500 to 600° C. and is rapidly cooled under a wind pressure condition of 15 to 30 kPa, but is not particularly limited thereto.

In addition, the tempering treatment layer 13 may be formed by the chemical tempering process in which one surface of the glass core 11 is immersed in molten salt to perform an ion-exchange reaction. For example, the molten salt may be defined as follows. For example, if potassium nitrate (KNO₃) is put into a bath and a temperature is heated to about 380° C., potassium nitrate (KNO₃) is changed to a liquid state. This potassium nitrate in the liquid state may be referred to as the molten salt. Next, if the bath has a temperature condition of 450 to 500° C. and one surface of the glass core 11 is immersed in the bath into which the molten salt is put for several hours, the ion-exchange reaction is performed in which sodium (Na⁺) ions are moved from a surface of the immersed glass core 11 and potassium (K⁺) ions are substituted into the positions from which sodium ions are moved, thereby making it possible to form the tempering treatment layer 13 having compression stress on the surface of the glass core 11, but the present disclosure is not particularly limited thereto.

In addition, the providing of the insulating layer 30 may include forming the tempering treatment layer 13 on one surface of the glass core 11 and polishing and removing a portion of the tempering treatment layer 13 in a thickness direction. By the configuration as described above, a thickness of the insulating layer 30 is further decreased, thereby making it possible to manufacture a thinned printed circuit board 100.

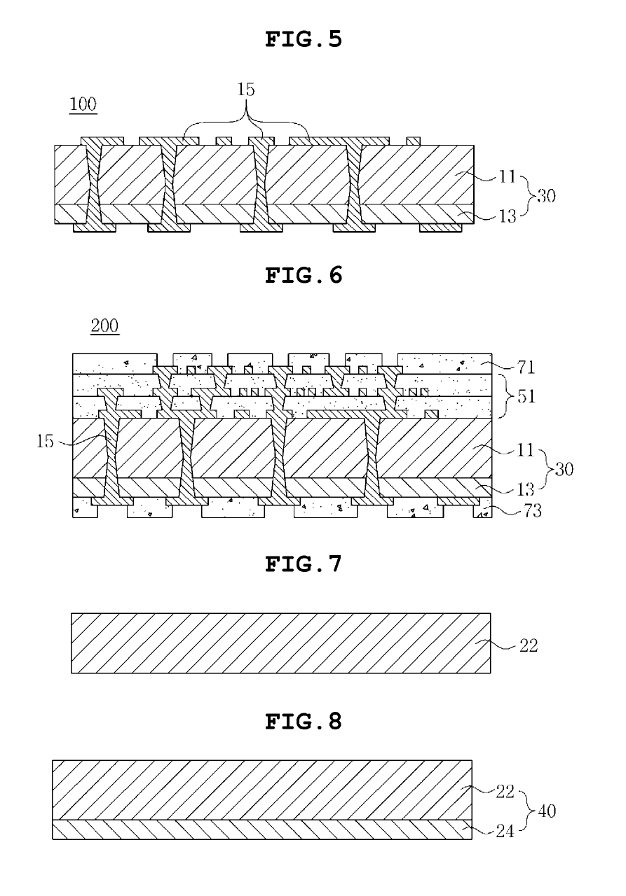

Referring to FIG. 5, in the method of manufacturing the printed circuit board 100 according to an exemplary embodiment of the present disclosure, a circuit layer 15 may be formed on the insulating layer 30. The circuit layer 15 may have a via hole and the circuit layer 15 including a circuit pattern formed on one surface or the other surface thereof may be formed. Here, the via hole may be machined by a drilling process such as a CO₂ or Yag laser drill. After the hole is machined, in order to remove burr and smear of copper foil caused by a drilling work, deburring and desmear processes may be performed.

Next, the via hole may be filled with conductive paste. Here, as a material of the conductive paste which is subsequently cured to form the circuit layer 15 including the circuit pattern, any material may be used as long as it has conductive property. For example, silver (Ag), palladium (Pd), platinum (Pt), nickel (Ni), silver/palladium (Ag/Pd), and the like may be used, but the present disclosure is not particularly limited thereto. The conductive paste filled into the via hole may be protruded over the insulating layer 30 as much as a height of the circuit pattern.

The circuit pattern may form the circuit layer 15 including a via by depositing a metal layer on the via hole and both surfaces of the insulating layer 30. The deposition may be formed by a sputtering process, and the metal layer is not particularly limited, but may be formed by using copper (Cu) taking account of several aspects.

Accordingly, the insulating layer 30 having the circuit 15 formed according to an exemplary embodiment of the present disclosure may prevent the warpage of the build-up layer 51 and allow a thinned printed circuit board 110 to be manufactured by serving as a supporting body supporting the build-up layer 51 later.

Referring to FIG. 6, the method of manufacturing the multi-layer printed circuit board 200 according to an exemplary embodiment of the present disclosure may further include, after the forming of the circuit layer 15, forming a build-up layer 51 including a build-up insulating layer and a build-up circuit layer on one surface of the circuit layer 15. By the configuration as described above, the printed circuit board according to an exemplary embodiment of the present disclosure may be formed in an asymmetrical shape.

In addition, the method of the multi-layer printed circuit board may further include, after the forming of the build-up layer 51, forming a solder resist layer 71 on the outermost layer of the build-up layer 51. The solder resist layer 71 may be formed on the outermost layer of the build-up layer 51 to protect and electrical insulate the circuit pattern. The solder resist layer 71 may be provided with an open part to expose a connection terminal formed on the outermost layer of the build-up layer 51 connected to other electronic products. In addition, the solder resist layer 73 may also be formed on a surface of the insulating layer 30 on which the build-up layer 51 is not formed.

### Second Exemplary Embodiment

FIGS. 7 through 10 are cross-sectional views showing a manufacturing process flow in order to describe a method of manufacturing a printed circuit board according to another exemplary embodiment of the present disclosure.

Referring to FIG. 7, a method of manufacturing a printed circuit board 110 according to another exemplary embodiment of the present disclosure may include preparing a glass core 22.

Referring to FIG. 8, the method of manufacturing the printed circuit board 110 according to another exemplary embodiment of the present disclosure may include providing an insulating layer 40 by forming a tempering treatment layer 24 on one surface of the glass core 22.

In addition, the providing of the insulating layer 40 may include forming the tempering treatment layer 24 on one surface of the glass core 22 and polishing and removing a portion of the tempering treatment layer 24 in a thickness direction. By the configuration as described above, a thickness of the insulating layer 40 is further decreased, thereby making it possible to manufacture a thinned printed circuit board 110.

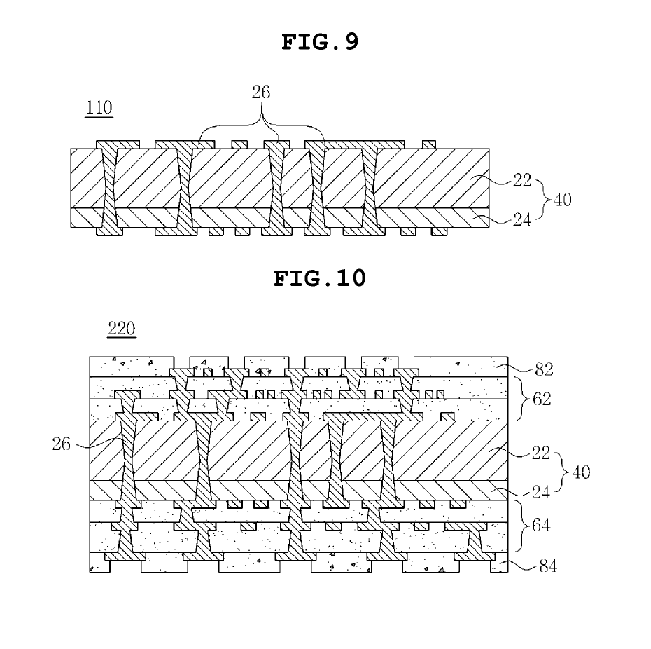

Referring to FIG. 9, in the method of manufacturing the printed circuit board 110 according to another exemplary embodiment of the present disclosure, a circuit layer 26 may be formed on the insulating layer 40. The circuit layer 26 may have a via hole and the circuit layer 26 including a circuit pattern formed on one surface or the other surface thereof may be formed.

Accordingly, the insulating layer 40 having the circuit layer 26 formed according to another exemplary embodiment of the present disclosure may prevent the warpage of build-up layers 62 and 64 and allow a thinned printed circuit board 110 to be manufactured by serving as supporting bodies supporting the build-up layers 62 and 64 later.

Referring to FIG. 10, the method of manufacturing the multi-layer printed circuit board 220 according to another exemplary embodiment of the present disclosure may further include, after the forming of the circuit layer 26, forming build-up layers 62 and 64 including a build-up insulating layer and a build-up circuit layer on one surface and the other surface of the circuit layer 26. In this case, the multi-layer printed circuit board may be formed in a symmetrical or asymmetrical shape by stacking thicknesses of the build-up layer 62 stacked on one surface of the circuit layer 26 and the build-up layer 64 stacked on the other surface of the circuit layer 26 to be equal to each other or be different from each other. By the configuration as described above, when designing additional stacking processes on an upper and lower portions of the multi-layer printed circuit board 220, the build-up layers 62 and 64 are formed in the symmetrical shape or the asymmetrical shape, thereby making it possible to appropriately adjust the warpage.

In addition, the method of the printed circuit board may further include, after the forming of the build-up layers 62 and 64, forming solder resist layers 82 and 84 on the outermost layers of the build-up layers 62 and 64.

In the method of manufacturing the printed circuit board according to another exemplary embodiment of the present disclosure, since the technical contents about the insulating layer including the glass core and the tempering treatment layer, the circuit layer, the build-up layer, and the solder resist layer, and the description about the method of manufacturing the same are substantially equal to those described in the method of manufacturing the printed circuit board according to an exemplary embodiment of the present disclosure, the overlapped contents will be omitted.

As set forth above, in the printed circuit board according to an exemplary embodiment of the present disclosure, the problem about the warpage may be minimized by the printed circuit board in which the insulating layer including the glass core and the tempering treatment layer formed on one surface of the glass core is embedded.

In addition, in the printed circuit board according to an exemplary embodiment of the present disclosure, the problem about the warpage may be solved in the strip or unit shape of the printed circuit board having different stiffness of the upper surface and the lower surface, and the warpage of the panel unit may be minimized.

In addition, the insulating layer according to an exemplary embodiment of the present disclosure may provide the printed circuit board having the thin thickness and the improved bending strength by using the glass core.

In addition, in the case in which the build-up layer having the vertically asymmetrical structure about the insulating layer is formed, the printed circuit board capable of selectively adjusting the warpage according to the product design may be provided.

In the method of manufacturing the printed circuit board according to an exemplary embodiment of the present disclosure, the printed circuit board that is resistant to the warpage may be manufactured at low cost by forming the insulating layer using the air cooled tempering process.

In addition, the insulating layer may be formed by using the chemical tempering process rather than the air cooled tempering process, thereby making it possible to manufacture the printed circuit board having improved heat-resistant property.

Although the embodiments of the present disclosure have been disclosed for illustrative purposes, it will be appreciated that the present disclosure is not limited thereto, and those skilled in the art will appreciate that various modifications, additions and substitutions are possible, without departing from the scope and spirit of the disclosure.

Accordingly, any and all modifications, variations or equivalent arrangements should be considered to be within the scope of the disclosure, and the detailed scope of the disclosure will be disclosed by the accompanying claims.

What is claimed is:

1. A printed circuit board comprising:
an insulating layer including a glass core and a tempering treatment layer formed on one surface of the glass core; and
a circuit layer formed on the insulating layer.

2. The printed circuit board of claim 1, wherein the tempering treatment layer is formed by treating one surface of the glass core by an air cooled tempering process.

3. The printed circuit board of claim 1, wherein the tempering treatment layer is formed by treating one surface of the glass core by a chemical tempering process.

4. The printed circuit board of claim 1, further comprising a build-up layer including a build-up insulating layer and a build-up circuit layer on one surface or the other surface of the circuit layer.

5. The printed circuit board of claim 4, further comprising a solder resist layer formed on the outermost layer of the build-up layer.

6. A method of manufacturing a printed circuit board, the method comprising:
preparing a glass core;
providing an insulating layer by forming a tempering treatment layer on one surface of the glass core; and
forming a circuit layer on the insulating layer.

7. The method of claim 6, wherein in the forming of the tempering treatment layer, the tempering treatment layer is formed by treating one surface of the glass core by an air cooled tempering process.

8. The method of claim 6, wherein in the forming of the tempering treatment layer, the tempering treatment layer is formed by treating one surface of the glass core by a chemical tempering process.

9. The method of claim 6, wherein the forming of the circuit layer on the insulating layer includes:
forming a via hole in the insulating layer by a laser machining; and
forming the circuit layer including a via by depositing a metal layer on the via hole and both surfaces of the insulating layer.

10. The method of claim 6, further comprising, after the forming of the circuit layer, forming a build-up layer including a build-up insulating layer and a build-up circuit layer on one surface or the other surface of the circuit layer.

11. The method of claim 10, further comprising, after the forming of the build-up layer, forming a solder resist layer on the outermost layer of the build-up layer.

12. The method of claim 6, wherein the providing of the insulating layer includes:
forming the tempering treatment layer on one surface of the glass core; and
polishing and removing a portion of the tempering treatment layer in a thickness direction.
